(19) United States
(12) Patent Application Publication
(10) Pub. No.: US 2022/0141993 A1
(43) Pub. Date: May 5, 2022

(54) COOLING APPARATUS, COOLING SYSTEM, AND COOLING METHOD

(71) Applicant: NEC Corporation, Tokyo (JP)

(72) Inventors: Kenji KOBAYASHI, Tokyo (JP); Kunihiko ISHIHARA, Tokyo (JP); Koichi TODOROKI, Tokyo (JP); Yoshinori MIYAMOTO, Tokyo (JP); Minoru YOSHIKAWA, Tokyo (JP)

(73) Assignee: NEC Corporation, Tokyo (JP)

(21) Appl. No.: 17/505,805

(22) Filed: Oct. 20, 2021

(30) Foreign Application Priority Data
Oct. 29, 2020 (JP) 2020-181677

(51) Int. Cl. H05K 7/20

(52) U.S. Cl. CPC H05K 7/20145; H05K 7/20745; H05K 7/20172

(57) ABSTRACT

A cooling apparatus includes a duct provided above a cooling target and configured to guide an air discharged after absorbing heat generated inside the cooling target to the cooling target, a cooler provided in the duct and configured to cool the air flowing in the duct, and an adjusting mechanism provided downstream of the cooler and configured to adjust the air discharged from the duct to the cooling target, and the duct receives the air discharged from one side of the cooling target and directed upward, guides the air to another side of the cooling target, and discharges the air downward on the other side, and the adjusting mechanism changes a position of an opening at a discharge port of the duct.

### CROSS REFERENCE TO RELATED APPLICATION

This application is based upon and claims the benefit of priority from Japanese Patent Application No. 2020-181677 filed in Japan on Oct. 29, 2020, the content of which is incorporated herein its entirety by reference.

### TECHNICAL FIELD

The present invention relates to a cooling apparatus, a cooling system, and a cooling method.

### BACKGROUND ART

As a technology related to an apparatus for efficiently cooling electronic devices installed in a room such as a data center or a server room, there is a cooling scheme in which a cold air (air having a temperature lower than an outside air temperature or room temperature) generated by an air conditioner is blown up from under a floor of a cold aisle (a passage space on a side in which the electronic devices installed in the room suction the cold air) in the room. In relation to this technology, Japanese Unexamined Patent Application, First Publication No. 2014-142106 (hereinafter referred to as “Patent Document 1”) is known.

Patent Document 1 discloses a technology in which low-temperature air is caused to flow in electronic devices to perform efficient cooling by supplying cold air from an air conditioning apparatus to an underfloor space of a server room, blowing the cold air from the underfloor space into a cold aisle, which is a passage between one shelf (a so-called rack that accommodates heating elements such as electronic devices; hereinafter referred to as a “housing”) in the server room and another adjacent housing, and causing the cold air to be suctioned into the electronic devices so that heat is exchanged with heat generating components or the like therein.

Generally, the density of a gas becomes higher as the temperature becomes lower. Therefore, in the cooling scheme described in Patent Document 1, while the cold air having a high density blown up from under the floor is unlikely to rise and tends to accumulate on a lower side of the cold aisle, the air that has absorbed heat of the electronic devices and has a low density tends to easily rise. Due to such a phenomenon in which a difference in density of a gas occurs depending on a temperature, a temperature distribution occurs in the vertical direction (a temperature distribution in which a temperature rises toward an upper side) of the housing. Therefore, in the electronic devices vertically disposed in the housing, an electronic device disposed on an upper portion tends to have a higher temperature of the cold air suctioned in for cooling the electronic device.

Moreover, in order to correct the tendency in which the temperature of the cold air suctioned into the electronic device on the upper portion becomes high, Patent Document 1 described above employs a configuration of actively supplying the cold air to the electronic device on the upper portion by providing a local cooler above the housing and supplying the cold air downward from the local cooler.

Furthermore, Japanese Unexamined Patent Application, First Publication No. 2012-33105 (hereinafter referred to as “Patent Document 2”) that is related to Patent Document 1 discloses an air conditioning system in which a cooling unit is provided in a space above a housing in addition to supplying cold air from under the floor. In this air conditioning system, air that rises due to increase in temperature and decrease in density after absorbing heat in electronic devices is cooled by the cooling unit, and then the air is discharged downward to cause the electronic devices to suction the air again.

In Patent Document 2, the air cooled by the cooling unit and having an increased density flows downward, and the electronic device inside the housing suctions the air, so that the air can absorb heat therein.

### SUMMARY

However, generally, in an installation situation in which a plurality of electronic devices are vertically stacked to be accommodated in a housing, there is a problem in that it is difficult to keep suctioned cold air at a predetermined management temperature or less so as to efficiently cool each of the plurality of electronic devices that are vertically stacked simply by blowing out the cold air in both upward and downward directions.

An example object of the present invention is to efficiently cool electronic devices disposed in an air-conditioned room.

In order to solve the above-described problems, the present invention proposes the following means.

A cooling apparatus according to a first example aspect includes a duct provided above a cooling target and configured to guide air discharged after absorbing heat generated inside the cooling target to the cooling target; a cooler provided in the duct and configured to cool the air flowing in the duct; and an adjusting mechanism provided downstream of the cooler and configured to adjust the air discharged from the duct to the cooling target, wherein the duct receives the air discharged from one side of the cooling target and directed upward, guides the air to another side of the cooling target, and discharges the air downward on the other side, and the adjusting mechanism changes a position of an opening at a discharge port of the duct.

A cooling method according to a second example aspect includes: cooling air discharged after absorbing heat generated inside a cooling target installed in an air-conditioned room; discharging the cooled air to the cooling target; and adjusting a position to which the discharged air is discharged.

According to the present invention, electronic devices installed in a room can be efficiently cooled.

### BRIEF DESCRIPTION OF THE DRAWINGS

FIG. 1 is a cross-sectional view of a cooling apparatus according to an example of a minimum configuration of the present invention.

FIG. 2 is a flow chart of a cooling method according to the example of the minimum configuration of the present invention.

FIG. 3 is a perspective view of a cooling apparatus according to a first example embodiment viewed from above.

FIG. 4 is a cross-sectional view of a state in which the cooling apparatus according to the first example embodiment is disposed above an electronic device in a housing as a cooling target.

FIGS. 5A to 5C are views explaining an operation of an adjusting mechanism according to the first example embodiment.

FIG. 6 is an arrangement plan of temperature measurement points in the first example embodiment.

### EXAMPLE EMBODIMENT

An example of a minimum configuration of the present invention will be described with reference to FIG. 1.

Reference sign 1 indicates a duct. The duct 1 guides air discharged after absorbing heat generated inside a cooling target not illustrated in FIG. 1 (e.g., an electronic device such as a server accommodated in a rectangular parallelepiped housing) to the cooling target not illustrated in FIG. 1 below the duct 1. The duct 1 includes a cooler 2 that cools an air flowing inside the duct 1, and an adjusting mechanism 3 that adjusts an air discharged from the duct 1 into a room in which the cooling target is installed on a downstream side of the cooler 2.

With the above-described configuration, an air discharged from the cooling target flows in an arrow “a” direction in FIG. 1 and is sent to the cooler 2 to be cooled, flows into the duct 1 as illustrated by an arrow “b” in FIG. 1, and is sent downward as illustrated by an arrow “c” in FIG. 1 to be suctioned into the cooling target.

Moreover, the adjusting mechanism 3 adjusts the position of the air discharged from the duct 1, for example, in a left-right direction (horizontal direction) of FIG. 1. Due to this adjustment, the position of the airflow downward from the duct 1 can be changed in the horizontal direction. Due to the change, for example, when the position of the airflow is on a right side in FIG. 1 (when the position of the airflow is separated from the cooling target), the downward airflow goes straight ahead further downward, and a larger amount of cold air can be supplied to the cooling target away from the duct 1 (disposed below the duct 1). Additionally, due to the change, when the position of the airflow is on a left side in FIG. 1 (when the position of the airflow is brought close to the cooling target), the cold air is immediately suctioned into a cooling target closer to the duct 1 (disposed on an upper side) among the cooling targets below the duct 1 and thus a larger amount of cold air can be supplied.

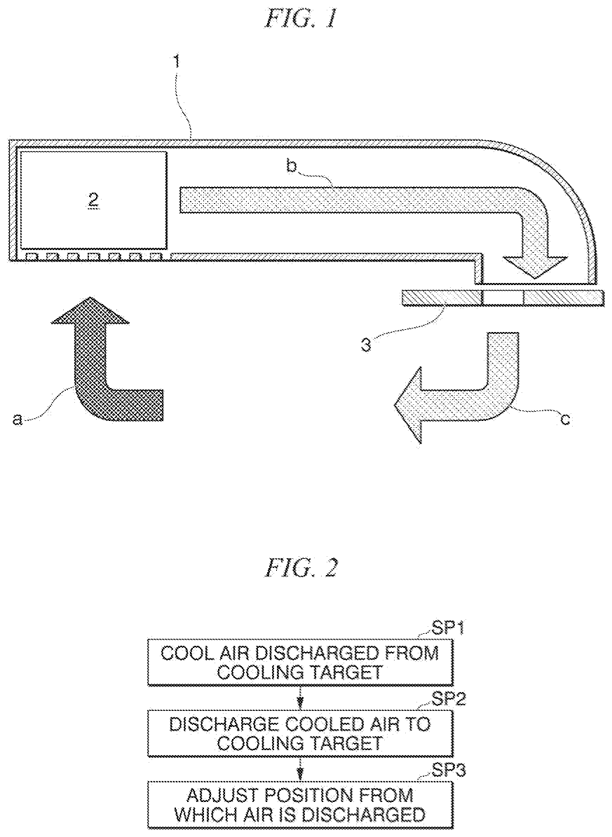

A cooling method according to the example of the minimum configuration of the present invention will be described with reference to FIG. 2.

The cooling method includes a step SP1 of cooling an air discharged after absorbing heat generated inside the cooling target installed in an air-conditioned room, a step SP2 of discharging the cooled air to the cooling target, and a step SP3 of adjusting the position from which the discharged air is discharged.

With the above-described configuration, an air that has absorbed heat generated inside the cooling target can be cooled and then discharged toward the cooling target. Moreover, by adjusting the position from which the cooled air is discharged at the time of the discharge, an amount of air supplied to the cooling target disposed on an upper side and a cooling target disposed on a lower side among the cooling targets disposed below the cooling apparatus can be adjusted, and non-uniformity in an amount of supplied air can be reduced.

### First Example Embodiment

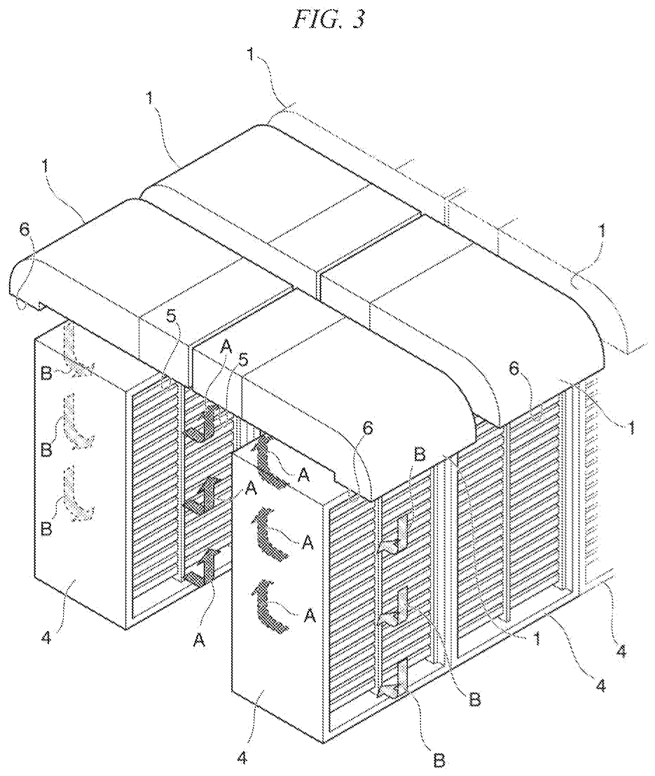

A first example embodiment of the present invention will be described with reference to FIGS. 3 to 6. It should be noted that in FIGS. 3 to 6, components which are the same as those in FIG. 1 are denoted by the same reference signs, and a description thereof will be simplified.

FIG. 3 illustrates an example of a server room in which a cooling system including a plurality of cooling apparatuses according to the first example embodiment is accommodated.

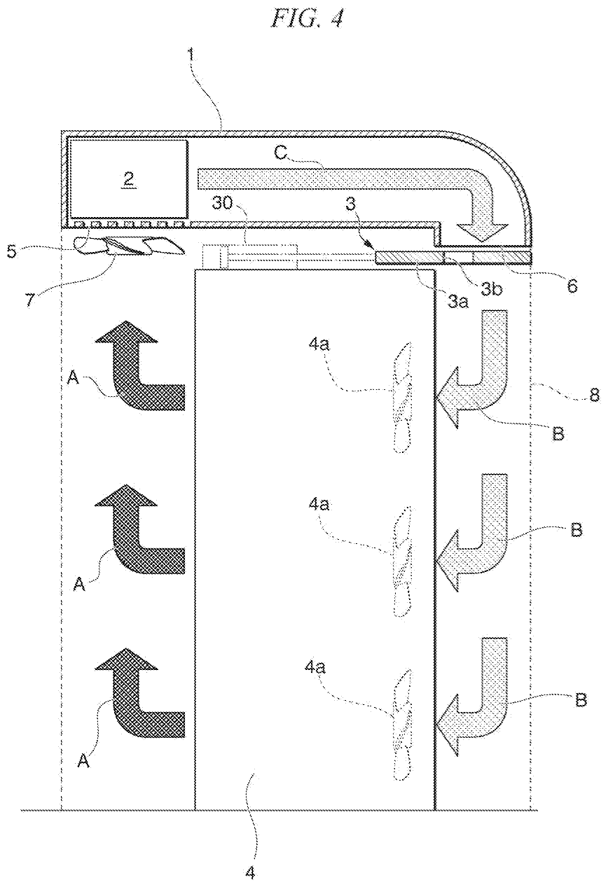

A plurality of cooling targets 4 are installed in the server room. The cooling targets 4 are, for example, electronic devices such as data servers vertically disposed in multiple stages in a frame-shaped or box-shaped housing. It should be noted that in FIG. 4, for the sake of convenience, the cooling targets 4 are configured to be stacked in three stages. However, generally, the cooling targets 4 are often stacked in more than three stages. There may also be a configuration in which the cooling targets 4 are stacked in less than three stages as a matter of course.

Each of ducts 1 guides an air suctioned from a suction port 5 as illustrated by an arrow “A” to a discharge port 6 and discharges the air downward as illustrated by an arrow “B” above each of the cooling targets 4. Moreover, the adjusting mechanism 3 (not illustrated in FIG. 3) disposed on the discharge port side of the duct 1 adjusts the position and amount of the air discharged from the discharge port 6 by deforming a cross-sectional shape of the discharge port 6. It should be noted that the inside of the server room is kept at a predetermined temperature by an air conditioning apparatus (not illustrated). Generally, a region in which an air discharged from a cooling target 4 flows as illustrated by the arrow “A” is referred to as a hot aisle, and a region in which an air suctioned into a cooling target 4 flows as illustrated by the arrow “B” is referred to as a cold aisle.

FIG. 4 illustrates one cross section of the cooling apparatus illustrated in FIG. 3. Fans 4a are incorporated in an electronic devices constituting a cooling target 4. The fans 4a suction an air in the server room in a left direction of FIG. 4 (in a direction in which a distal end of the arrow “B” points) and discharge the air from a left side of the cooling target 4. The air flowing inside the cooling target 4 is discharged after absorbing heat generated by heat generating elements or the like inside the cooling target 4, expands while absorbing the heat in the cooling target 4, decreases in density, and rises as illustrated by the arrow “A” in FIG. 4. It should be noted that the fans 4a are provided for a housing of each of the electronic devices constituting the cooling targets 4, but the number of fans 4a (and the electronic devices) is not limited to the example of FIG. 4.

A fan 7 is provided at the suction port 5 of the duct 1. The fan 7 suctions the air rising in the arrow “A” direction and sends the suctioned air into the duct 1 via the suction port 5. It should be noted that the fans 4a and the fan 7 correspond to a cross-sectional shape of the duct 1 and, for example, are small fans having a radius of rotation corresponding to the dimension of a short side in the cross section of the duct 1, and the numbers of fans 4a and 7 corresponding to the dimension of a long side in the cross section of the duct 1 are aligned (the fans 4a and the fan 7 are aligned in a direction perpendicular to the paper surface of FIG. 4).

The cooler 2 is provided at a position immediately above the suction port 5 of the duct 1. The cooler 2 is, for example, a heat exchanger that cools the air suctioned in the arrow “A” direction by utilizing the endothermic action due to expansion of a heat medium such as a low-pressure refrigerant. The air that has passed through the cooler 2 is guided by the duct 1, flows in the arrow “C” direction to be discharged from the discharge port 6, is suctioned into the cooling target 4 in the arrow “B” direction, absorbs internal heat again, and is discharged in the arrow “A” direction. A refrigerant (heat medium) is supplied to the cooler 2 from a compressor (not illustrated) such as a turbo compressor. In the first example embodiment, a pipe conduit is formed so that the refrigerant from a main refrigerant supply pipe (not illustrated) is distributed and supplied to a plurality of coolers 2, and undergoes heat exchange, and then the refrigerant flows leaving the coolers 2 are recovered after merging in a main refrigerant return pipe (not illustrated).

The discharge port 6 of the duct 1 is provided to be directed downward and is configured to discharge the cooled air that has passed through the duct 1 downward from above the cooling target 4.

The adjusting mechanism 3 is provided below the discharge port 6.

The adjusting mechanism 3 includes an adjusting plate 3a disposed to cross the discharge port 6, and a rectangular opening 3b provided to penetrate a part of the adjusting plate 3a and forming a part of a cross-sectional shape of the discharge port 6. It should be noted that the adjusting plate 3a of the adjusting mechanism 3 in the first example embodiment may be configured to slide left and right by a manual operation, and may be configured to be movable in a left-right direction of FIG. 4 by, for example, an actuator 30 such as a pneumatic cylinder illustrated by a dot-dash line in FIG. 4. Furthermore, a sheet-shaped guide plate 8 that suppresses diffusion of the air discharged from the discharge port 6 into the server room and guides the air downward is provided at a position below the discharge port 6 of the duct 1. It should be noted that the guide plate 8 is formed using an easily deformable material having a curtain or blind form that can be easily opened and closed in consideration of workability when accessing a front surface or a back surface of the electronic device as the cooling target 4.

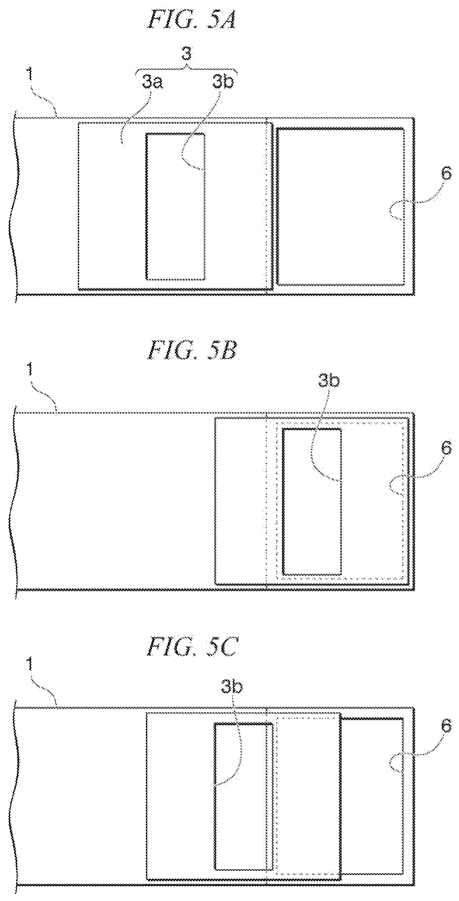

A cooling method and its operation performed in the cooling apparatus of the first example embodiment will be described with reference to FIGS. 5A to 5C. It should be noted that in the illustrated example, the opening 3b is formed in a central region (a range of one-third of the entire adjusting plate 3a) among regions obtained by dividing the adjusting plate 3a constituting the adjusting mechanism 3 into three equal sections in the left to right direction. However, the position, shape, and area of the opening 3b are not limited to the illustrated example. Moreover, in the illustrated example, the adjusting mechanism 3 is configured so that a range of two-thirds of the adjusting plate 3a has the same shape as the cross-sectional shape of the discharge port 6.

FIG. 5A illustrates a state in which the adjusting mechanism 3 is at a position that does not overlap the discharge port 6 and the discharge port 6 is fully open.

FIG. 5B illustrates a state in which the opening 3b of the adjusting mechanism 3 is positioned on a left side in FIG. 5B of the discharge port 6, and the discharge port 6 has been opened to an area equal to the area corresponding to the opening 3b and 50% of the area of the discharge port 6 when the discharge port 6 is fully open.

FIG. 5C illustrates a state in which the opening 3b of the adjusting mechanism is at a position further toward the left side than in FIG. 5B, the opening 3b is at a position that does not overlap the discharge port 6, and a part of the adjusting plate 3a (a range of one-third on the right side) covers the discharge port 6 so that the discharge port 6 is opened by 50% of the area when the discharge port 6 is fully open.

In FIG. 5A, the adjusting plate 3a has been retracted to a position that does not overlap the discharge port 6 and the discharge port 6 is fully open, and thus all the cold air can be supplied downward along the cooling target 4. Here, the guide plate 8 is provided along the cooling target 4, and thus the cold air can be guided downward while the cold air downward is inhibited from flowing out to the cold aisle.

In FIG. 5B, the adjusting plate 3a is positioned on the left side of the discharge port 6 and the opening 3b is positioned close to the cooling target 4, and thus the cold air is easily suctioned into the cooling target 4 disposed on the upper side, and a larger amount of cold air can be supplied to the cooling target on the upper side. Moreover, the cold air can be guided by the guide plate 8 while the cold air downward further is inhibited from flowing out to the cold aisle.

In FIG. 5C, the adjusting plate 3a is positioned further toward the left side of the discharge port 6, a distal end of the adjusting plate 3a covers a position on the left side of the discharge port 6, and a position on the right side of the discharge port 6 is open, and thus the cold air is more likely to be suctioned into the cooling target 4 disposed on the lower side than the cooling target 4 disposed on the upper side, and a larger amount of cold air can be supplied to the cooling target on the lower side. Moreover, the cold air can be guided downward by the guide plate 8 while the cold air is inhibited from flowing out to the cold aisle.

In this manner, in the first example embodiment, a blowoff position (the position of the opening 3b in the cross section of the discharge port 6) and an amount (and/or a flow velocity of the blowoff due to the adjustment of the opening area) of the cold air discharged from the discharge port 6 can be adjusted by moving the adjusting plate 3a in the horizontal direction. With such adjustment of a blowoff position and air flow rate (and/or a wind velocity), the cold air with a required air flow rate can be supplied to cooling targets 4 at different heights.

It should be noted that the actuator 30 that operates the adjusting mechanism 3 may be manually operated, for example, at the discretion of the operator, and when a load and a temperature distribution of the cooling target 4 can be predicted, the position of the adjusting plate 3a may be fixedly set in any of the example aspects illustrated in FIGS. 5A to 5C without using an actuator.

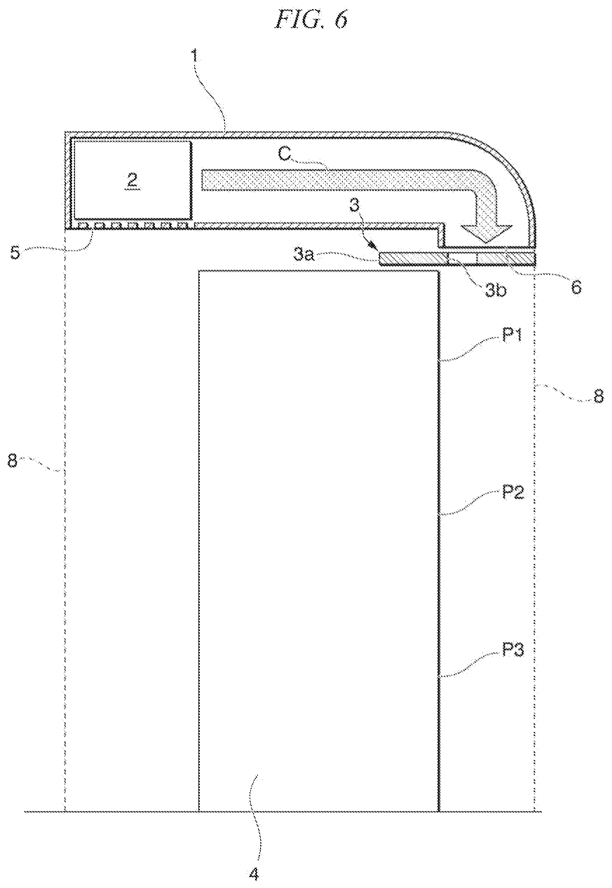

An experimental example of temperature control using the adjusting mechanism 3 of the first example embodiment will be described with reference to FIG. 6 and Table 1.

Here, dimensions of a rack as the cooling target 4 are 2.1 m in height, 0.8 m in width, and 0.65 m in depth. Moreover, a flow rate of air flowing through the duct 1 due to the fan 7 is 20 m³/min. Furthermore, regarding heights of temperature measurement points, P1 is 1.5 m, P2 is 0.9 m, and P3 is 0.3 m.

TABLE 1

| | | Example 1 of Present invention | | | Conventional |
|---|---|---|---|---|---|
| | | A | B | C | example |
| Rack | P1: Upper | 18.2 | 17.5 | 19.2 | 23.7 |
| measurement | P2: Middle | 17.7 | 17.8 | 18.3 | 22.3 |
| position | P3: Lower | 17.5 | 18.1 | 17.6 | 20.2 |
| | Average | 17.8 | 17.8 | 18.4 | 22.1 |
| Temperature | Maximum − Minimum | 0.7 | 0.6 | 1.6 | 3.5 |
| variations | Variance | 0.13 | 0.09 | 0.64 | 3.10 |
| | Upper − Middle | 0.5 | −0.3 | 0.9 | 1.4 |
| | Middle − Lower | 0.2 | −0.3 | 0.7 | 2.1 |

Unit: ° C.

As shown in Table 1, in any of the states of FIGS. 5A to 5C (columns A, B, and C in Table 1), it was ascertained that temperature variations at the temperature measurement points P1, P2, and P3 were curbed compared to a conventional example (with a condition in which the discharge port 6 is fully open and all cold air is discharged) in which the adjusting mechanism 3 was not provided in the discharge port 6 of the duct 1.

### Second Example Embodiment

In view of the measurement results in Table 1, as an optimum operation example of assuring a temperature for a rack server using the present invention, implementation in the following example aspects is effective even when the rack has two servers having different heat loads.

(1) When a lower server has a large heat load:

The adjusting mechanism 3 is set under the condition A or C in Table 1, and a sensor for temperature assurance management is attached to a lower side of the rack.

When a temperature at the position of the lower server can be made equal to or less than an assurance temperature of the server, it is also possible to assure the temperature of an upper server which has a smaller heat load than the lower server.

(2) When the upper server has a large heat load:

The adjusting mechanism 3 is set under the condition B in Table 1, and a sensor for temperature assurance management is attached to an upper side of the rack.

When a temperature at the position of the upper server can be made equal to or less than the assurance temperature of the server, it is also possible to assure the temperature of the lower server which has a smaller heat load than the upper server.

That is, all of cooling targets can be managed such that they are at an assured temperature by utilizing only temperature measurement values measured at some temperature measurement points among a plurality of temperature measurement points at different heights without providing temperature sensors for the cooling targets at different heights and measuring temperatures at a plurality of temperature measurement points corresponding to the cooling targets.

The configuration of the above-described adjusting mechanism is not limited to the example embodiment and any other mechanism that can adjust the position of the air discharged from the duct or the flow rate thereof together with the position, for example, a mechanism that deflects the direction of the guide plate may also be employed as a matter of course.

It should be noted that a configuration in which the adjusting mechanism 3 is operated using the actuator 30 may be employed, and the actuator 30 may be operated by automatic control in accordance with a determination result of a cooling status of the cooling target 4 by a control unit that controls air conditioning of the server room and a control unit that manages intake/exhaust temperatures or the like of the electronic device serving as the cooling target.

While example embodiments of the present invention have been described in detail with reference to the drawings, the specific configurations are not limited to the example embodiments and may include design changes or the like within a range not departing from the gist of the present invention.

The present invention can be utilized in cooling apparatuses, cooling systems, and cooling methods.

What is claimed is:

1. A cooling apparatus comprising:
a duct provided above a cooling target and configured to guide air discharged after absorbing heat generated inside the cooling target to the cooling target;
a cooler provided in the duct and configured to cool the air flowing in the duct; and
an adjusting mechanism provided downstream of the cooler and configured to adjust the air discharged from the duct to the cooling target,
wherein the duct receives the air discharged from one side of the cooling target and directed upward, guides the air to another side of the cooling target, and discharges the air downward on the other side, and
the adjusting mechanism changes a position of an opening at a discharge port of the duct.

2. The cooling apparatus according to claim 1, wherein the adjusting mechanism is an adjusting plate provided to be movable in a direction perpendicular to a flow of the air at the discharge port of the duct.

3. The cooling apparatus according to claim 2, wherein the opening is provided in the adjusting plate and forms a part of a cross-sectional shape of the discharge port of the duct.

4. The cooling apparatus according to claim 1, wherein the duct, the cooler, and the adjusting mechanism are provided for each of a plurality of cooling targets.

5. The cooling apparatus according to claim 1, wherein the cooling target is an electronic device and transfers heat to an air flowing from one side to the other side in a horizontal direction.

6. A cooling system comprising:
the cooling apparatus according to claim 1; and
the cooling target,
wherein the duct suctions the air from a side in which the cooling target discharges the air and supplies the air to a side in which the cooling target suctions the air.

7. A cooling method comprising:
cooling air discharged after absorbing heat generated inside a cooling target installed in an air-conditioned room;
discharging the cooled air to the cooling target; and
adjusting a position to which the discharged air is discharged.

8. The cooling method according to claim 7, further comprising:
measuring temperatures at positions in the vicinity of the cooling target at different heights; and
adjusting the position to which the discharged air is discharged in accordance with the temperatures measured at the positions at the different heights.
